(19) United States
(12) Patent Application Publication
(10) Pub. No.: US 2024/0053451 A1
(43) Pub. Date: Feb. 15, 2024

(54) LIGHT-RECEIVING DEVICE AND RANGE FINDING APPARATUS

(71) Applicant: CANON KABUSHIKI KAISHA, Tokyo (JP)

(72) Inventors: Koichi FUKUDA, Tokyo (JP); Kohei OKAMOTO, Kanagawa (JP); Shunichi WAKASHIMA, Tokyo (JP); Takashi HANASAKA, Tokyo (JP)

(21) Appl. No.: 18/492,655

(22) Filed: Oct. 23, 2023

Related U.S. Application Data
(63) Continuation of application No. PCT/JP2022/014806, filed on Mar. 28, 2022.

(30) Foreign Application Priority Data
Apr. 26, 2021 (JP) 2021-074414

(51) Int. Cl. G01S 7/487; G01S 7/4863

(52) U.S. Cl. CPC G01S 7/4876; G01S 7/4863

(57) ABSTRACT

Disclosed is a light-receiving device having a wide dynamic range. The light receiving device comprises a pixel array in which a first pixel provided with a first optical band pass filter and having a first sensitivity and a second pixel provided with a second optical band pass filter and having a second sensitivity that is lower than the first sensitivity are two-dimensionally arranged. A full width at half maximum of the second optical band pass filter is narrower than a full width at half maximum of the first optical band pass filter.

### CROSS-REFERENCE TO RELATED APPLICATIONS

This application is a Continuation of International Patent Application No. PCT/JP2022/014806, filed Mar. 28, 2022, which claims the benefit of Japanese Patent Applications No. 2021-74414 filed Apr. 26, 2021, both of which are hereby incorporated by reference herein in their entirety.

### BACKGROUND OF THE INVENTION

### Field of the Invention

The present invention relates to a light-receiving device and a range finding apparatus.

### Background Art

There are known ToF (Time-of-Flight) range-finding methods for measuring a distance to an object that has reflected light, by measuring a time difference between a time when light was emitted and a time when reflected light was detected. The ToF range-finding accuracy depends on the measurement accuracy of the time difference. For this reason, in order to increase the range-finding accuracy, there is a need to increase the measurement accuracy of the time difference.

As a method for increasing the measurement accuracy of the time difference, it is conceivable to shorten a delay time from when reflected light is received until when the light is detected. In PTL1, in a light detector in which a plurality of light receiving elements are two-dimensionally arranged, SPADs (Single Photon Avalanche Diodes) are used in the light receiving elements.

Each SPAD generates an avalanche current when a photon is incident, as a result of an avalanche photodiode being operated in Geiger mode. Since a time period from when a photon is incident until when an avalanche current is generated is short, namely on the order of 10⁻¹² seconds, and thus a timing when reflected light is received can be accurately detected.

In addition, PTL2 discloses a pixel array in which two types of light receiving elements (SPADs) having different sensitivities are arranged, in order to increase the dynamic range.

### CITATION LIST

### Patent Literature

PTL1: Japanese Patent Laid-Open No. 2014-081254
PTL2: Japanese Patent Laid-Open No. 2019-190892

Two types of SPADs used in PTL2 have different physical structures and different voltages are applied thereto, and thus characteristics of the SPADs such as temporal response characteristics differ for each type of SPAD. For this reason, a measurement time that is obtained differs depending on a type of SPAD, which is disadvantageous in terms of the range finding accuracy. In addition, when SPADs having different physical structures are manufactured on one chip, there is a risk that a manufacturing process will be complicated and variation in characteristics of SPADs will be large.

### SUMMARY OF THE INVENTION

The present invention provides, as its one aspect, a new technique for realizing a light-receiving device that has a wide dynamic range.

According to an aspect of the present invention, there is provided a light-receiving device comprising a pixel array in which a first pixel provided with a first optical band pass filter and having a first sensitivity and a second pixel provided with a second optical band pass filter and having a second sensitivity that is lower than the first sensitivity are two-dimensionally arranged, wherein a full width at half maximum of the second optical band pass filter is narrower than a full width at half maximum of the first optical band pass filter.

According to another aspect of the present invention, there is provided a range finding apparatus comprising: a light-receiving device; and one or more processors that execute a program stored in a memory and thereby function as: a measuring unit configured to measure time periods from a predetermined time until times when light is incident on the first pixel and the second pixel, respectively; and a computing unit configured to compute distance information for the first pixel and distance information for the second pixel based on the measured time periods, wherein the light-receiving device comprising a pixel array in which a first pixel provided with a first optical band pass filter and having a first sensitivity and a second pixel provided with a second optical band pass filter and having a second sensitivity that is lower than the first sensitivity are two-dimensionally arranged, wherein a full width at half maximum of the second optical band pass filter is narrower than a full width at half maximum of the first optical band pass filter.

According to a further aspect of the present invention, there is provided an electronic device comprising: a range finding apparatus; and one or more processors that execute a program stored in a memory and thereby function as a processing unit configured to execute predetermined processing using distance information obtained by the range finding apparatus, wherein the range finding apparatus comprises: a light-receiving device; and one or more processors that execute a program stored in a memory and thereby function as: a measuring unit configured to measure time periods from a predetermined time until times when light is incident on the first pixel and the second pixel, respectively; and a computing unit configured to compute distance information for the first pixel and distance information for the second pixel based on the measured time periods, wherein the light-receiving device comprising a pixel array in which a first pixel provided with a first optical band pass filter and having a first sensitivity and a second pixel provided with a second optical band pass filter and having a second sensitivity that is lower than the first sensitivity are two-dimensionally arranged, wherein a full width at half maximum of the second optical band pass filter is narrower than a full width at half maximum of the first optical band pass filter.

Further features of the present invention will become apparent from the following description of exemplary embodiments with reference to the attached drawings.

### BRIEF DESCRIPTION OF THE DRAWINGS

FIG. 1 is a block diagram showing an exemplary functional configuration of a range finding apparatus 100 that uses a light-receiving device according to an embodiment of the present invention.

FIG. 2A is a diagram showing a configuration example of a light source unit 111.

FIG. 2B is a diagram showing a configuration example of the light source unit 111.

FIG. 2C is a diagram showing a configuration example of the light source unit 111.

FIG. 3A is a diagram showing an example of a light-projection pattern of the light source unit 111.

FIG. 3B is a diagram showing an example of a light-projection pattern of the light source unit 111.

FIG. 4 is an exploded perspective view schematically showing a mounting example of the measurement unit 120.

FIG. 5A is a diagram related to a configuration example the light-receiving part 121.

FIG. 5B is a diagram related to a configuration example the light-receiving part 121.

FIG. 6A is a diagram showing an example of the spectroscopic characteristics of an optical bandpass filter that is provided in a pixel 511.

FIG. 6B is a diagram showing an example of the spectroscopic characteristics of an optical bandpass filter that is provided in a pixel 511.

FIG. 7 is a vertical cross-sectional view showing a configuration example of the light receiving element of a pixel 511.

FIG. 8A is a diagram showing an example of potential distribution on a cross-section in FIG. 7.

FIG. 8B is a diagram showing an example of potential distribution on a cross-section in FIG. 7.

FIG. 8C is a diagram showing an example of potential distribution on a cross-section in FIG. 7.

FIG. 9 is a circuit diagram showing a configuration example of a pixel 511.

FIG. 10 is a block diagram showing a configuration example of a TDC array unit 122.

FIG. 11 is a circuit diagram showing a configuration example of a high resolution TDC 1501.

FIG. 12 is a diagram related to operations of the high resolution TDC 1501.

FIG. 13 is a timing chart related to a range-finding operation.

FIG. 14 is a timing chart obtained by enlarging a portion of FIG. 13.

FIG. 15 is a diagram schematically showing an exemplary circuit configuration of a second oscillator 1512 of a low resolution TDC 1502.

FIG. 16 is a block diagram showing an exemplary functional configuration of a first oscillation adjusting circuit 1541 and a second oscillation adjusting circuit 1542.

FIG. 17 is a flowchart related to an example of a range-finding operation according to an embodiment of the present invention.

FIG. 18A is a diagram showing an example of a histogram of range-finding results.

FIG. 18B is a diagram showing an example of a histogram of range-finding results.

FIG. 18C is a diagram showing an example of a histogram of range-finding results.

FIG. 18D is a diagram showing an example of a histogram of range-finding results.

FIG. 18E is a diagram showing an example of a histogram of range-finding results.

### DESCRIPTION OF THE EMBODIMENTS

Hereinafter, the present invention will be described in detail based on exemplary embodiments thereof with reference to the attached drawings. Note that the following embodiments are not intended to limit the scope of the claimed invention. A plurality of features are described in the embodiments, but all of the features are not necessarily essential to the present invention, and some features may be combined as appropriate. Furthermore, in the attached drawings, the same reference numerals are given to the same or similar configurations, and a redundant description thereof is omitted.

Note that, in the present specification, the characteristics of light receiving elements being the same indicates that the physical configurations and bias voltages of the light receiving elements are not made different in a proactive manner. Therefore, there can be a difference in characteristics due to inevitable factors such as manufacturing variation.

### First Embodiment

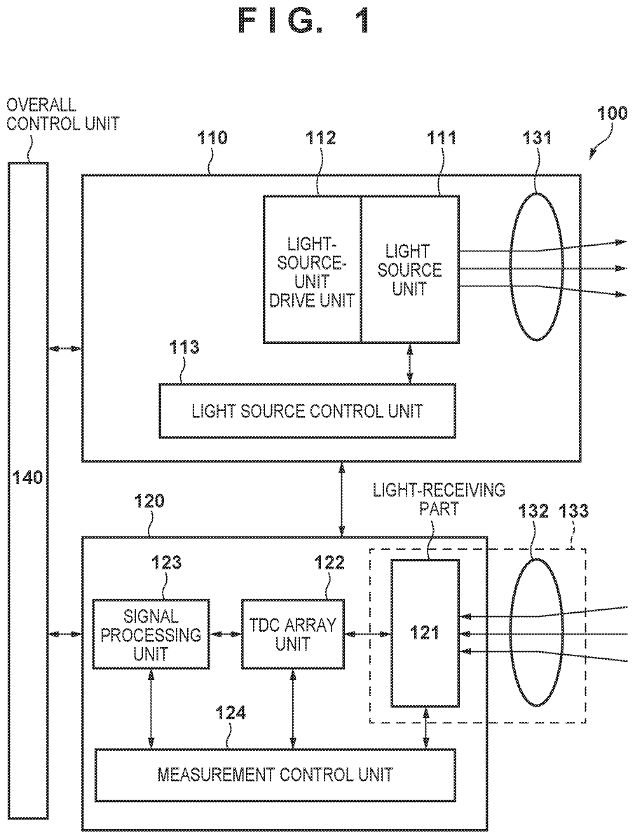

FIG. 1 is a block diagram showing an exemplary functional configuration of a range finding apparatus that uses a light-receiving device according to the present invention. A range finding apparatus 100 includes a light-projection unit 110, a measurement unit 120, a light-receiving lens 132, and an overall control unit 140. The light-projection unit 110 includes a light source unit 111 in which light-emitting elements are arranged in a two-dimensional array, a light-source-unit drive unit 112, a light source control unit 113, and a light-projection lens 131. The measurement unit 120 includes a light-receiving part 121, a Time-to-Digital Convertor (TDC) array unit 122, a signal processing unit 123, and a measurement control unit 124. Note that, in the present specification, a combination of the light-receiving lens 132 and the light-receiving part 121 may be referred to as a “light-receiving unit 133”.

The overall control unit 140 controls the overall operations of the range finding apparatus 100. The overall control unit 140 includes a CPU, a ROM, and RAM, for example, and controls the constituent elements of the range finding apparatus 100 by loading a program stored in the ROM to the RAM, and the CPU executing the program. At least a portion of the overall control unit 140 may be realized by a dedicated hardware circuit.

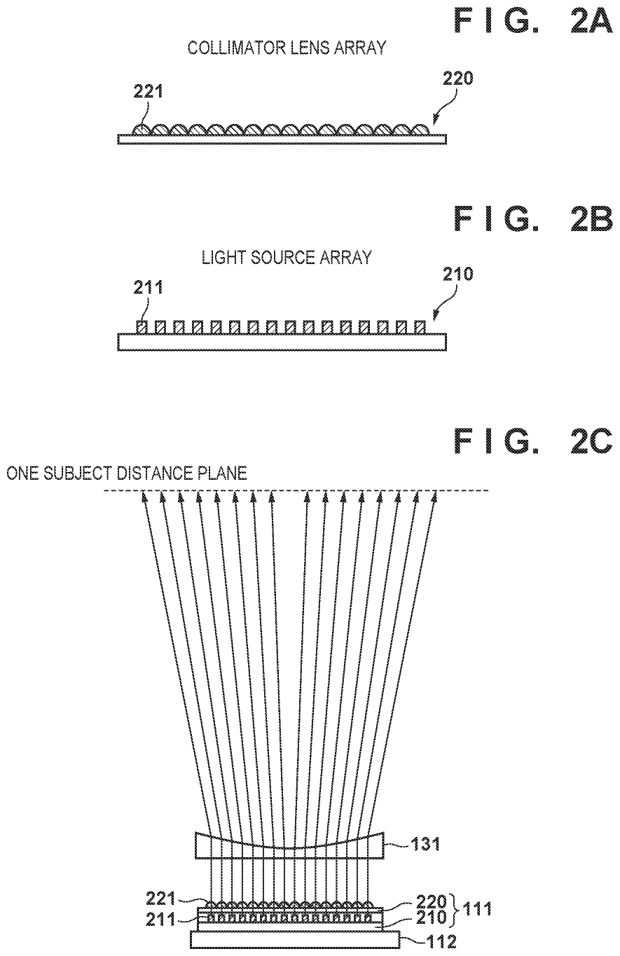

By causing a plurality of light-emitting elements 211 (FIG. 2B) arranged in the light source unit 111 to emit light for a short time, pulsed light (pulse light) is emitted via the light-projection lens 131. Pulse light beams emitted from the individual light-emitting elements illuminate different spaces, respectively. A portion of the pulse light emitted from the light source unit 111 is reflected by a subject, and is incident on the light-receiving part 121 via the light-receiving lens 132. In the present embodiment, a configuration is adopted in which the light-emitting elements 211 that emit light and specific pixels among a plurality of pixels arranged in the light-receiving part 121 optically correspond to each other. Here, a pixel optically corresponding to a certain light-emitting element 211 is a pixel that is in a positional relation therewith such that a largest portion of reflected light of light emitted from the light-emitting element 211 is detected in the pixel.

A time period from when the light source unit 111 emits light until when reflected light of the light is incident on the light-receiving part 121 is measured as a ToF (Time-of-Flight) by the TDC array unit 122. Note that, in order to reduce the influence that noise components such as ambient light and a dark count or noise of the TDC array unit 122 have on a measurement result, a ToF (Time-of-Flight) is measured a plurality of times.

The signal processing unit 123 generates a histogram of measurement results obtained by the TDC array unit 122 performing measurement a plurality of times, and removes noise components based on the histogram. The signal processing unit 123 then computes a distance L of a subject by substituting a ToF (Time-of-Flight) obtained by averaging the measurement results from which the noise components have been removed, into Expression (1) below, for example.

L[m]=ToF[sec]*c[m/sec]/2 (1)

Note that “c” indicates the speed of light. In this manner, the signal processing unit 123 computes distance information for each pixel.

### Light-Projection Unit 110

A configuration example of the light-projection unit 110 will be described with reference to FIGS. 2A to 2C. FIG. 2A is a side view showing a configuration example of a collimator lens array 220 that constitutes the light source unit 111, and FIG. 2B is a side view showing a configuration example of a light source array 210 that constitutes the light source unit 111.

The light source array 210 has a configuration in which the light-emitting elements 211, which are vertical cavity surface emitting lasers (VCSELs), for example, are arranged in a two-dimensional array. On and off of the light source array 210 is controlled by the light source control unit 113. The light source control unit 113 can control on and off of the light source array 210 in units of light-emitting elements 211.

Note that elements other than VCSELs such as edge surface emitting laser elements or light-emitting diodes (LEDs) may also be used as the light-emitting elements 211. When edge surface emitting laser elements are used as the light-emitting elements 211, a laser bar on which elements are one-dimensionally arranged on a board, or a laser bar stack having a two-dimensional array configuration in which laser bars are stacked can be used as the light source array 210. In addition, when LEDs are used as the light-emitting elements 211, it is possible to use the light source array 210 in which LEDs are arranged in a two-dimensional array on a board.

Note that, although there is no particular limitation, if the emission wavelength of the light-emitting elements 211 is a wavelength of near-infrared band, it is possible to suppress the influence of ambient light. VCSELs can be manufactured using a material used in an edge surface emitting laser or a surface emitting laser, by performing a semiconductor process. When a configuration for discharging a laser beam having a wavelength of near-infrared band is adopted, a GaAs-based semiconductor material can be used. In this case, a dielectric multilayer film that forms a distributed Bragg reflection (DBR) reflection mirror constituting a VCSEL can be configured by alternately layering, in a periodical manner, two thin films made of materials having different refractive indexes (GaAs/AlGaAs). The wavelength of light emitted by the VCSEL can be changed by adjusting the element combination of a compound semiconductor, or the composition.

An electrode for injecting a current and hall into an active layer is provided in each of the VCSELs that make up a VCSEL array. By controlling the timing for injecting a current and hall into the active layer, any pulse light and modulated light can be discharged. The light source control unit 113 can individually drive the light-emitting elements 211, and can drive the light source array 210 in units of rows, columns, or rectangular regions.

In addition, the collimator lens array 220 has a configuration in which a plurality of collimator lenses 221 are arranged in a two-dimensional array such that each collimator lens 221 corresponds to one light-emitting element 211. A light beam emitted by the light-emitting element 211 is converted into a parallel light beam by the corresponding collimator lens 221.

FIG. 2C is a vertical cross-sectional view of an arrangement example of the light-source-unit drive unit 112, the light source unit 111, and the light-projection lens 131. The light-projection lens 131 is an optical system for adjusting a light-projection range of parallel light emitted from the light source unit 111 (the light source array 210). In FIG. 2C, the light-projection lens 131 is a concave lens, but may be a convex lens or an aspherical lens, or may be an optical system constituted by a plurality of lenses.

In the present embodiment, as an example, the light-projection lens 131 is configured such that light is emitted in a range of ±45 degrees from the light-projection unit 110. Note that, the light-projection lens 131 may be omitted by controlling a direction in which light is emitted, using the collimator lenses 221.

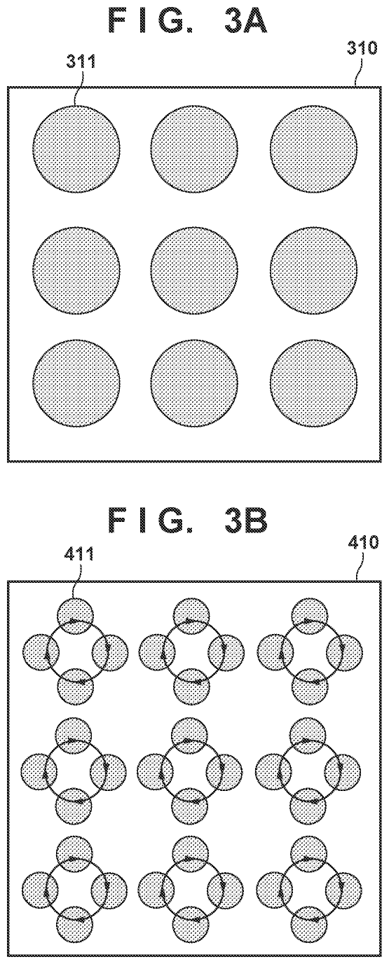

FIG. 3A shows a light-projection pattern that is formed by 3 rows×3 columns of light-emitting elements of the light source array 210, on a plane that directly faces a light-emission plane of the light-projection unit 110 and is at a predetermined distance. Nine light-projection areas 311 represent, on a plane 310, regions whose diameters are about the full width at half maximum (FWHM) of intensity distribution of light from the individual light-emitting elements.

A slight divergence angle is added, by the light-projection lens 131, to parallel light obtained as a result of the collimator lenses 221 converting light emitted from the light-emitting elements 211, and thus a limited region is formed on an irradiation plane (the plane 310). If the positional relation between the collimator lens array 220 and the light source array 210 is constant, the light-projection areas 311 are formed on the plane 310 so as to respectively correspond to the light-emitting elements 211 that make up the light source array 210.

The light-projection unit 110 according to the present embodiment includes the light-source-unit drive unit 112 that can move the light source unit 111 on the same plane. By the light-source-unit drive unit 112 moving the position of the light source unit 111, it is possible to change the relative positional relation between the light-emitting elements 211 and the collimator lenses 221 or the light-projection lens 131. A method for the light-source-unit drive unit 112 to drive the light source unit 111 is not particularly limited, but it is possible to use a mechanism that uses electromagnetic induction or piezoelectric elements, such as a mechanism that is used for driving image capturing elements in order to correct hand shaking.

When the light-source-unit drive unit 112 moves the light source unit 111 on a plane parallel to the board of the light source unit 111 (a plane perpendicular to the optical axis of the light-projection lens 131), for example, it is possible to move the light-projection areas 311 on the plane 310 substantially in parallel. By causing the light source unit 111 emit light a plurality of times while moving the light source unit 111 on a plane parallel to the board of the light source unit 111, for example, the space resolution of light-projection areas can be increased in a pseudo manner.

FIG. 3B shows a space resolution of light-projection areas 411 on a plane 410 when the light source unit 111 is turned on four times in a constant cycle while moving the light source unit 111 that includes the light source array 210 similar to that in FIG. 3A, so as to rotate in a circle once on a plane parallel to the board of the light source unit 111. A space resolution that is four-times higher than the space resolution in a case shown in FIG. 3A where the light source unit 111 is not moved is obtained.

Therefore, performing distance measurement in a state where relative positions between the light source unit 111 and the light-projection lens 131 differs, it is possible to increase the density of distance measurement points. It is possible to increase the space resolution of the light-projection area 411 without separating a light flux, and thus the measurable distance is not shortened, and the distance accuracy does not decrease due to a decrease in the intensity of reflected light.

Note that the relative positions between the light source unit 111 and the light-projection lens 131 may be changed by moving the light-projection lens 131 on a plane parallel to the board of the light source unit 111. Note that, if the light-projection lens 131 includes a plurality of lenses, the entire light-projection lens 131 may be moved, or only some lenses may be moved.

Furthermore, a configuration may also be adopted in which the light source unit 111 can be moved in a direction perpendicular to the board of the light source array 210 (optical axis direction of the light-projection lens 131) by the light-source-unit drive unit 112. Accordingly, it is possible to control the light divergence angle and the light projecting angle.

The light source control unit 113 controls light emission of the light source unit 111 (the light source array 210) in accordance with a light-receiving timing or the light-receiving resolution of the light-receiving unit 133.

### Measurement Unit 120

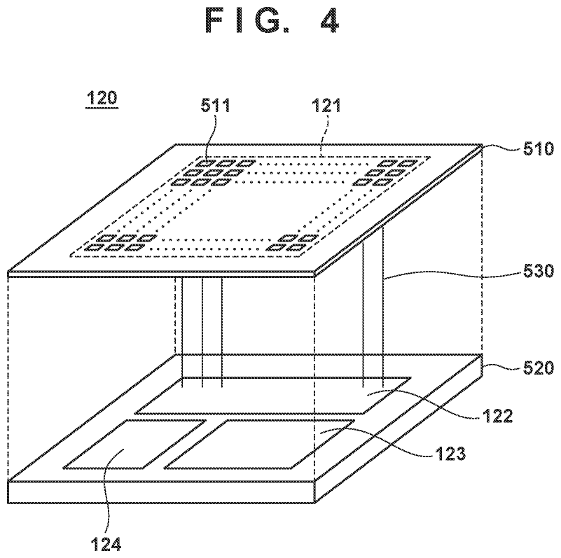

Next, a configuration of the measurement unit 120 will be described. FIG. 4 is an exploded perspective view schematically showing a mounting example of the measurement unit 120. FIG. 4 shows the light-receiving part 121, the TDC array unit 122, the signal processing unit 123, and the measurement control unit 124. The light-receiving part 121 and the TDC array unit 122 constitute a light-receiving device.

The measurement unit 120 has a configuration in which a light receiving element board 510 that includes the light-receiving part 121 in which the pixels 511 are arranged in a two-dimensional array, and a logic board 520 that includes the TDC array unit 122, the signal processing unit 123, and the measurement control unit 124 are stacked. The light receiving element board 510 and the logic board 520 are electrically connected to each other through inter-board connection 530. FIG. 4 shows the light receiving element board 510 and the logic board 520 in a state of being spaced from each other to facilitate description.

Note that functional blocks mounted on the boards are not limited to the illustrated example. A configuration may also be adopted in which three or more boards are stacked, or all of the functional blocks may be mounted on one board. The inter-board connection 530 is configured as Cu—Cu connection, for example, and one or more inter-board connections 530 may be disposed for each row of the pixels 511, or one inter-board connection 530 may be disposed for each pixel 511.

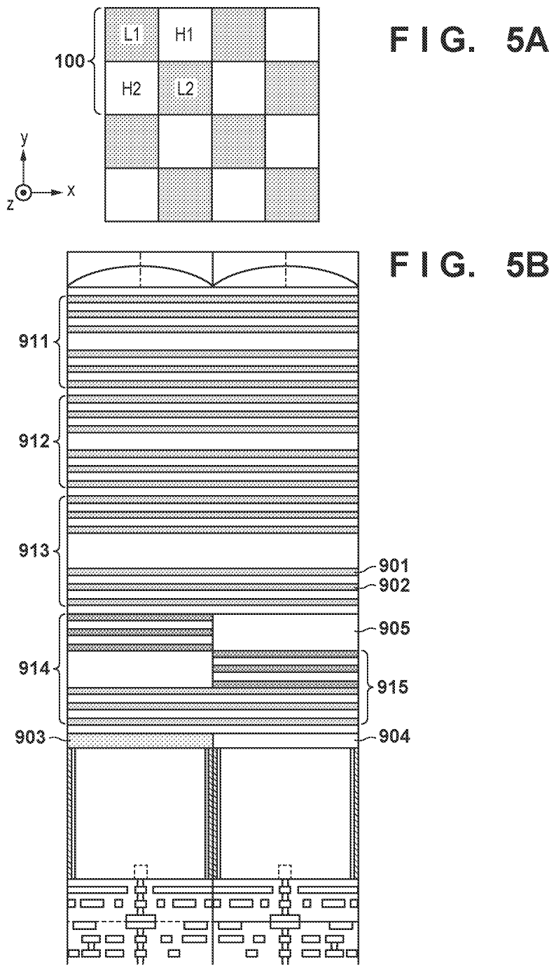

The light-receiving part 121 includes a pixel array in which the pixels 511 are arranged in a two-dimensional array. In the present embodiment, the light receiving elements of the pixels 511 are avalanche photodiodes (APD) or SPAD elements. In addition, as shown in FIG. 5A, pixels H (first pixels) having a first sensitivity and pixels L (second pixels) having a second sensitivity that is lower than the first sensitivity are alternately arranged in the row direction and the column direction. By arranging the pixels H and the pixels L adjacent to one another, offset correction of a pixel H that is based on a measurement result of a pixel L is enabled. In the present specification, the pixels H may also be referred to as “high-sensitivity pixels H”, and the pixels L may also be referred to as “low-sensitivity pixels L”.

FIG. 5B is a vertical cross-sectional view showing a structure example of pixels H and pixels L. Here, a resonance wavelength is denoted by λc, a refractive index of a high-refractive-index layer 901 is denoted by nH, and a refractive index of a low-refractive-index layer 902 is denoted by nL (<nH). Optical resonators 911 to 914 are multilayered film interference mirrors that (each) include a high-refractive-index layer 901 having a film thickness dH=0.25λc/nH and a low-refractive-index layer 902 having a film thickness dL=0.25λc/nL. A configuration is adopted in which a low-refractive-index layer 902 having a film thickness dE1 (to dE4)=m1 (to m4)×0.5λc/nL (m1 to m4 are natural numbers) is sandwiched by high-refractive-index layers 901 from the two sides.

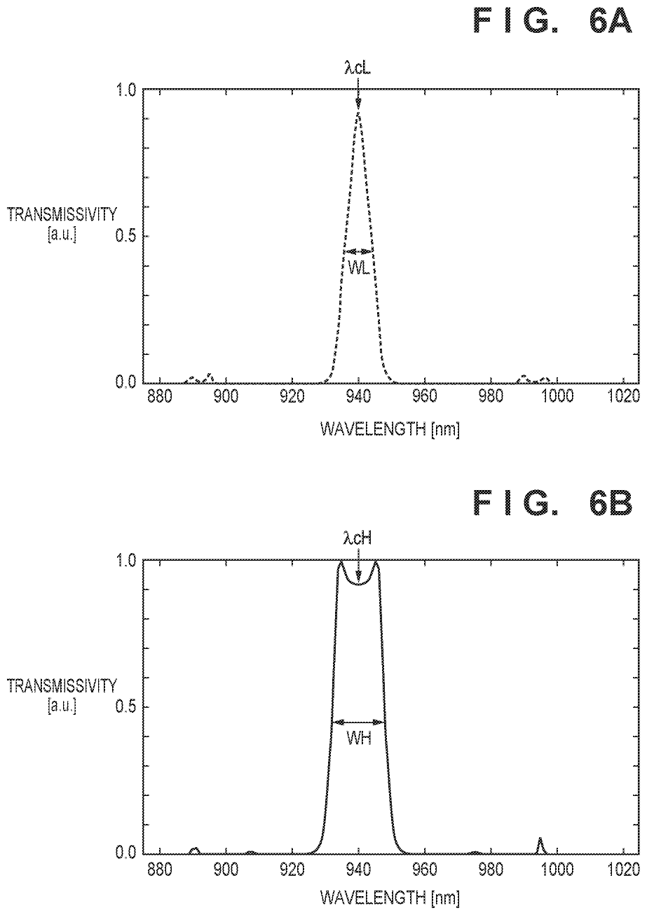

Each pixel L has a configuration in which a second optical bandpass filter is provided on top of a dimming layer 903 that is constituted by a thin tungsten film having a film thickness of 30 nm and that has transmissivity of about 45%. The second optical bandpass filter has a configuration in which the optical resonators 911 to 914 are layered, sandwiching the low-refractive-index layer 902 having the film thickness dL. The second optical bandpass filter has spectroscopic characteristics shown in FIG. 6A, and is an example of an optical component that is added to a light receiving element.

Each pixel H has a configuration in which a multilayered film interference mirror 915, a film thickness adjusting layer 905 constituted by a low-refractive-index layer and having the film thickness dE4, and a first optical bandpass filter are provided on top of a transmissivity layer 904 that is constituted by a low-refractive-index layer having a film thickness of 30 nm and that has a transmissivity of about 100%. The first optical bandpass filter is an example of an optical component that is added to a light receiving element, and has spectroscopic characteristics shown in FIG. 6B.

The first optical bandpass filter has a configuration in which the optical resonators 911 to 913 are layered, sandwiching the low-refractive-index layer 902 having the film thickness dL. The passbands of the first optical bandpass filter and the second optical band filter have basically the same central wavelength, and, in FIGS. 6A and 6B, λcL=λcH. The central wavelength can be the peak wavelength of light emitted by the light source unit 111. On the other hand, a full width at half maximum WL of the spectroscopic characteristics of the second optical bandpass filter is narrower than a full width at half maximum WH of the spectroscopic characteristics of the first optical bandpass filter.

The full width at half maximum WL is set narrower than the full width at half maximum WH, since it is envisioned that short distance range finding is mainly performed in the high-sensitivity pixels H while a long distance range finding is mainly performed in the low-sensitivity pixels L. In the low-sensitivity pixels L, the full width at half maximum WL is narrowed so as to be able to handle a long ToF, and noise light is kept from being measured before reflected light arrives.

In addition, the pixels L are configured to have a lower sensitivity than the pixels H as a result of being provided with the dimming layer 903. The dimming layer 903 is an example of an optical component for reducing the sensitivity of a pixel. Note that, in place of the dimming layer 903, another optical component such as masks that have different opening amounts may be used such that the pixels H and the pixels L have different sensitivities.

By providing, to each pixel L, a mask having an opening amount smaller than that of a mask provided in each pixel H, the light-receiving region of the light receiving element of the pixel L can be made narrower than the light-receiving region of the light receiving element of the pixel H, for example. It is not necessary to provide a mask to the pixel H, and, in this case, it suffices for a mask having an aperture ratio that is smaller than 100% to be provided to the pixel L. The mask can be formed of any material that can form a light shielding film.

In the present embodiment, instead of setting different configurations of light receiving elements themselves or different voltages that are applied thereto, an optical component that is added to a light receiving element is used to set different sensitivities of pixels. For this reason, the pixel H and the pixel L can have a common configuration of a light receiving element or a common voltage can be applied to the pixel H and the pixel L. Therefore, it is easy to manufacture the light receiving element array, and, in addition, it is possible to suppress variation in characteristics of light receiving elements.

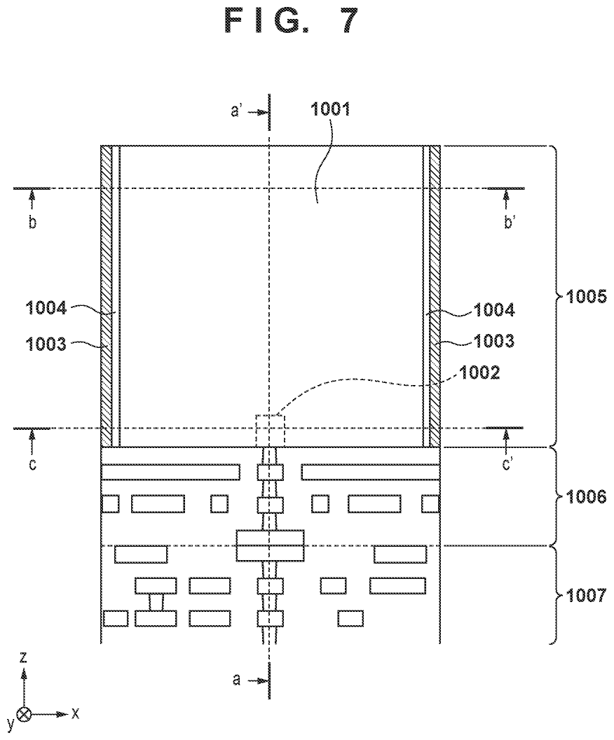

FIG. 7 is a cross-sectional view that includes a semiconductor layer of a light receiving element that is common to the pixels H and the pixels L. Reference numeral 1005 indicates a semiconductor layer of the light receiving element board 510, reference numeral 1006 indicates a wiring layer of the light receiving element board 510, and reference numeral 1007 indicates a wiring layer of the logic board 520. The light receiving element board 510 and the wiring layer of the logic board 520 are joined so as to face each other. The semiconductor layer 1005 of the light receiving element board 510 includes a light-receiving region (photoelectric conversion region) 1001, and an avalanche region 1002 for generating an avalanche current in accordance with a signal charge generated through photoelectric conversion.

In addition, a light shielding wall 1003 is provided between adjacent pixels in order to prevent light that has been obliquely incident on the light-receiving region 1001 of a pixel, from reaching the light-receiving region 1001 of an adjacent pixel. The light shielding wall 1003 is made of metal, and an insulator region 1004 is provided between the light shielding wall 1003 and the light-receiving region 1001.

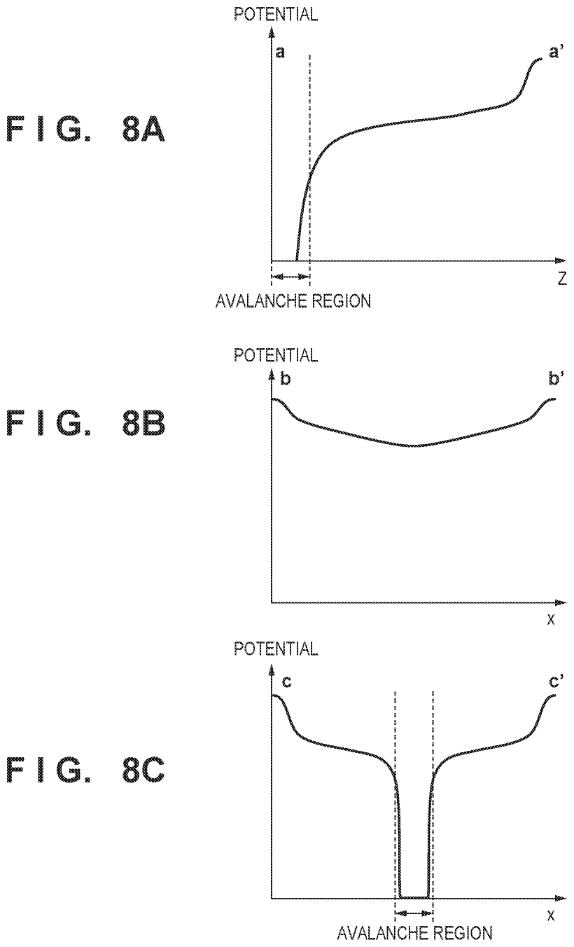

FIG. 8A is a diagram showing potential distribution of a semiconductor region in the cross-section a-a′ in FIG. 7. FIG. 8B is a diagram showing potential distribution in the cross-section b-b′ in FIG. 7. FIG. 8C is a diagram showing potential distribution of the cross-section c-c′ in FIG. 7.

Light that has been incident on the semiconductor layer 1005 of the light receiving element board 510 is subject to photoelectric conversion in the light-receiving region 1001, and an electron and a positive hole are generated. A positive hole carrying a positive electric charge is discharged via an anode electrode Vbd. As shown in FIGS. 8A, 8B, and 8C, an electron carrying a negative electric charge is transferred as a signal charge to the avalanche region 1002 due to an electric field that has been set such that the potential decreases toward the avalanche region 1002.

The signal charge that has arrived at the avalanche region 1002 causes avalanche breakdown, due to the strong electric field of the avalanche region 1002, and generates an avalanche current. This phenomenon occurs not only due to signal light (reflected light of light emitted by the light source unit 111) but also incidence of ambient light that is noise light, and generates noise components. In addition, a carrier is generated not only by incident light, but also generated thermally. An avalanche current caused by a thermally generated carrier is called a “dark count”, and becomes a noise component.

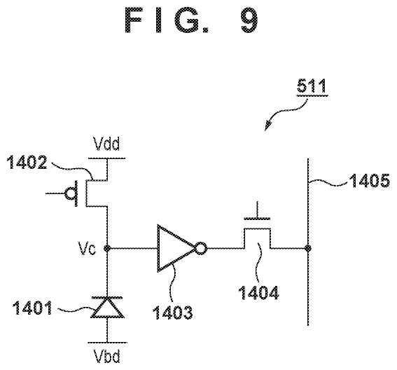

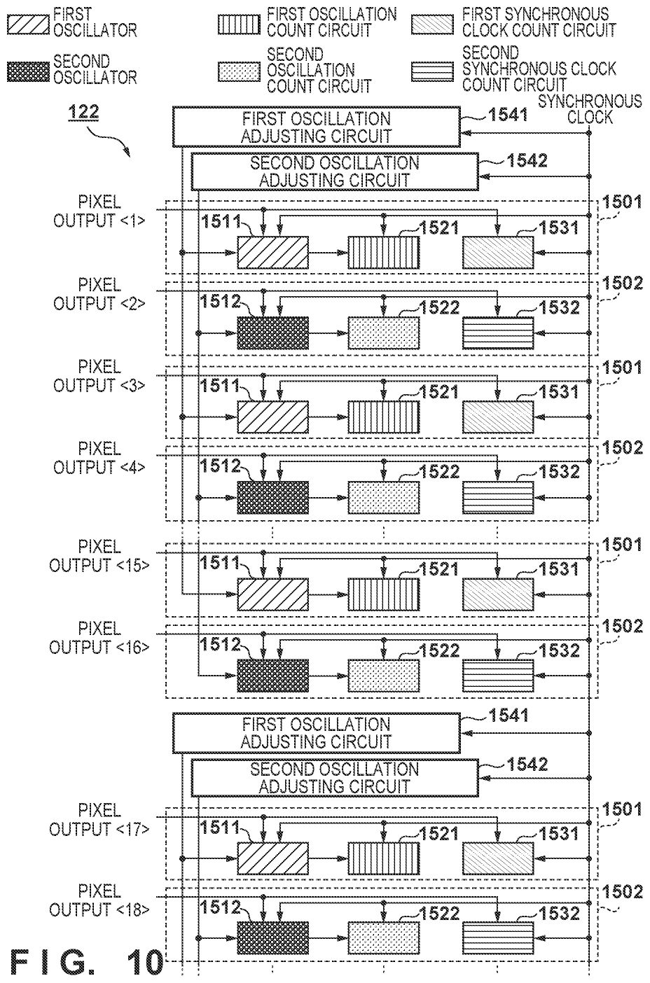

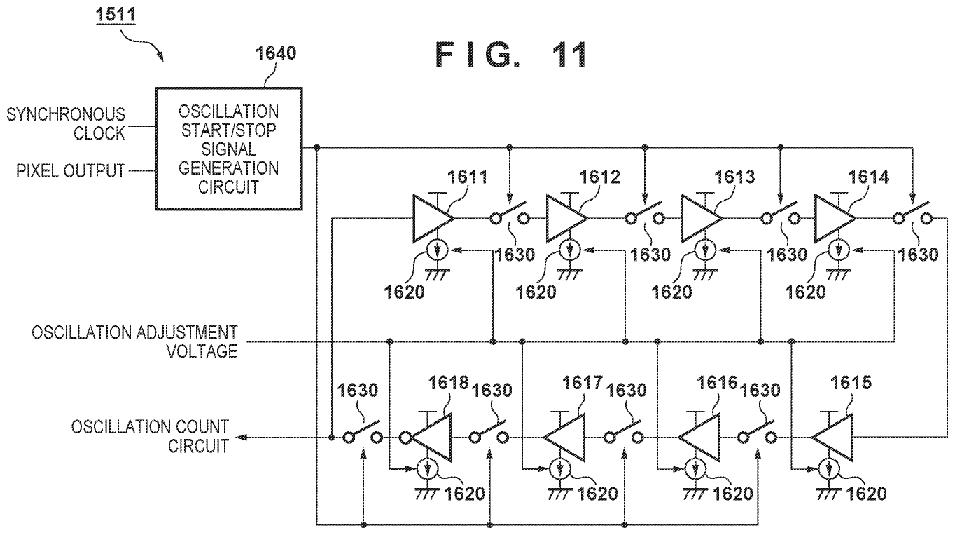

FIG. 9 is an equivalent circuit diagram of a pixel 511. The pixel 511 includes an SPAD element 1401, a load transistor 1402, an inverter 1403, a pixel select switch 1404, and a pixel output line 1405. The SPAD element 1401 corresponds to a region obtained by combining the light-receiving region 1001 and the avalanche region 1002 in FIG. 7.

When the pixel select switch 1404 is switched on by a control signal supplied from the outside, an output signal of the inverter 1403 is output to the pixel output line 1405 as a pixel output signal.

When no avalanche current is flowing, the voltage of the anode electrode Vbd is set such that a reverse bias that is larger than or equal to a breakdown voltage is applied to the SPAD element 1401. At this time, there is no current flowing through the load transistor 1402, and thus the voltage of a cathode potential Vc is close to a power supply voltage Vdd, and a pixel output signal thereof is “0”.

When an avalanche current is generated in the SPAD element 1401 due to arrival of a photon, the cathode potential Vc drops, and output of the inverter 1403 is reversed. That is to say, the pixel output signal changes from “0” to “1”.

When the cathode potential Vc drops, a reverse bias that is applied to the SPAD element 1401 drops, and when the reverse bias falls to a breakdown voltage or lower, generation of an avalanche current stops.

Thereafter, as a result of a positive hole current flowing from the power supply voltage Vdd via the load transistor 1402, the cathode potential Vc rises, output of the inverter 1403 (pixel output) returns from “1” to “0”, and the state returns to the state before the arrival of the photon. A signal output from the pixels 511 in this manner is input to the TDC array unit 122 via a relay buffer (not illustrated).

### TDC Array Unit 122

The TDC array unit 122 measures, as a ToF, a time period from a time when the light source unit 111 emits light until a time when the output signal of the pixel 511 changes from “0” to “1”.

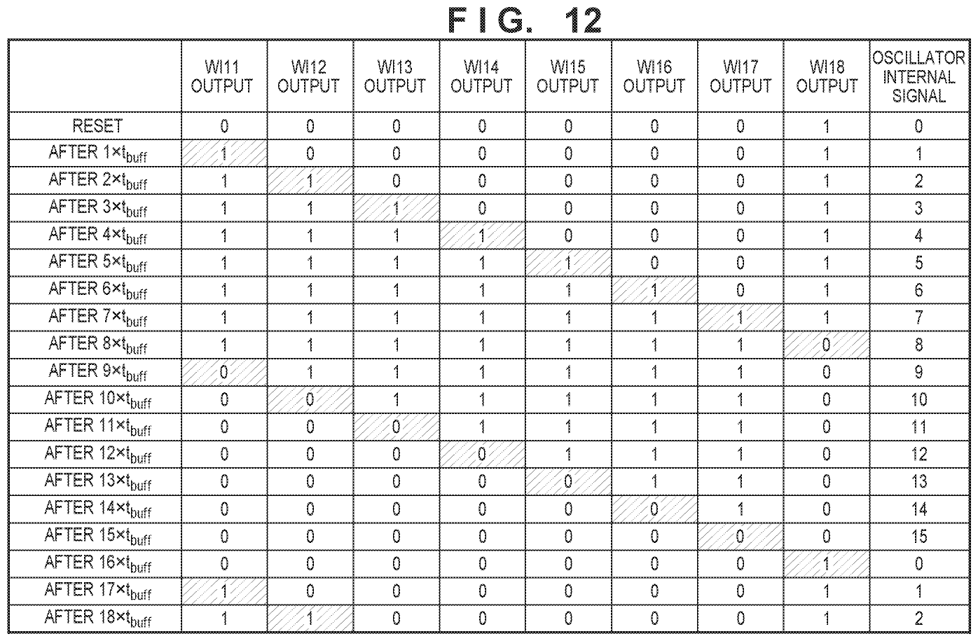

FIG. 10 is a diagram schematically showing a configuration example of the TDC array unit 122. In the TDC array unit 122, a high resolution TDC 1501 having a first measurement resolution is provided to half of the pixels that make up each pixel row of the pixel array, and a low resolution TDC 1502 having a second measurement resolution is provided to the other half, and thereby ToFs are measured in units of pixels. The second measurement resolution is lower than the first measurement resolution. In addition, a synchronous clock is supplied from the overall control unit 140, for example.

Here, an output signal of a high-sensitivity pixel H is driven by the relay buffer so as to be input to the high resolution TDC 1501, and an output signal of a low-sensitivity pixel L is driven by the relay buffer so as to be input to the low resolution TDC 1502. Specifically, regarding the high-sensitivity pixel H, a time period is measured with a higher measurement resolution than that of the low-sensitivity pixel L. In FIG. 10, an odd-numbered pixel output is output of a pixel H, and even-numbered pixel output is output of a pixel L. In order to substantially equalize delay times in relay buffers, the high resolution TDCs 1501 and the low resolution TDCs 1502 are alternately arranged.

Each high resolution TDC 1501 includes a first oscillator 1511, a first oscillation count circuit 1521, and a first synchronous clock count circuit 1531. The low resolution TDC 1502 includes a second oscillator 1512, a second oscillation count circuit 1522, and a second synchronous clock count circuit 1532. The first oscillation count circuit 1521 and the second oscillation count circuit 1522 are second counters that count changes in output values of the corresponding oscillators. The first synchronous clock count circuit 1531 and the second synchronous clock count circuit 1532 are first counters that count synchronous clocks.

Regarding output values of the TDCs, counting results of the synchronous clock count circuits occupy higher bits, internal signals of the oscillators occupy lower bits, and counting results of the oscillation count circuits occupy intermediate bits. That is to say, a configuration is adopted in which the synchronous clock count circuits perform rough measurement, internal signals of the oscillators are used for minute measurement, and the oscillation count circuits perform intermediate measurement. Note that each measurement bit may include a redundant bit.

FIG. 11 is a diagram schematically showing a configuration example of the first oscillator 1511 of the high resolution TDC 1501. The first oscillator 1511 includes an oscillation start/stop signal generation circuit 1640, buffers 1611 to 1617, an inverter 1618, an oscillation switch 1630, and delay-adjusting current sources 1620. In addition, the buffers 1611 to 1617 and the inverter 1618, which are delay elements, are alternately connected to the oscillation switches 1630 in series in a ring shape. The delay-adjusting current sources 1620 are respectively provided to the buffers 1611 to 1617 and the inverter 1618, and adjust the delay times of the corresponding buffers and inverter in accordance with an adjusting voltage.

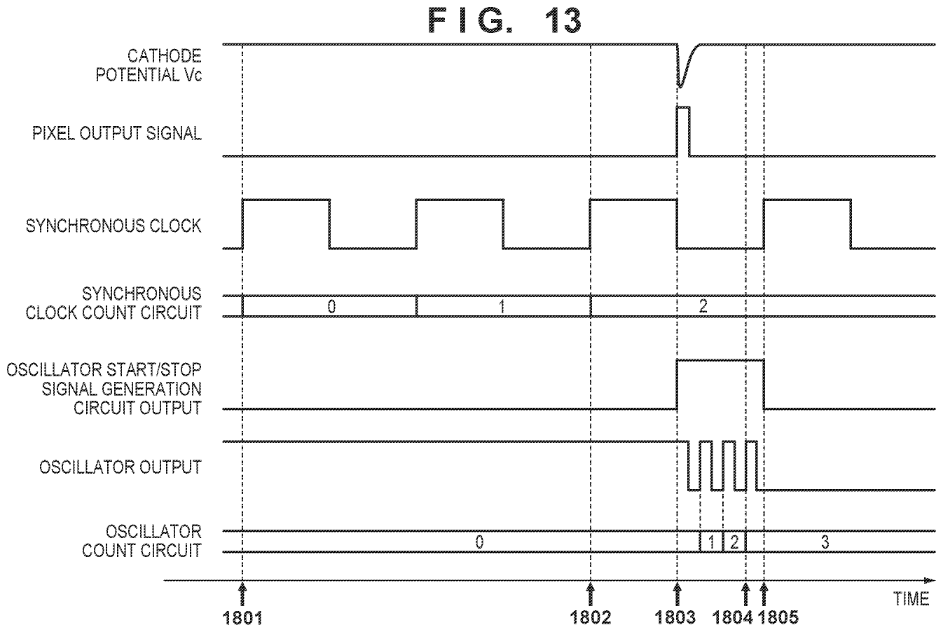

FIG. 12 shows changes in output signals of the buffers 1611 to 1617 and the inverter 1618 and an internal signal of the oscillator, at the time of resetting, and after each delay time t_{buff} corresponding to one buffer stage has elapsed from when the oscillation switch 1630 was switched on. WI11 output to WI18 output respectively represent output signals of the buffers 1611 to 1617 and the inverter 1618.

At the time of resetting, the output values of the buffers 1611 to 1617 are “0” and the output value of the inverter 1618 is “1”. After a delay time t_{buff} corresponding to one buffer stage has elapsed from when the oscillation switch 1630 was switched on, the output values of the buffers 1612 to 1617 and the inverter 1618 that are input/output consistent do not change. On the other hand, the output value of the buffer 1611 that is not input/output consistent changes from “0” to “1” (the signal proceeds by one stage).

When t_{buff} further elapses (after 2×t_{buff}), the output values of the buffer 1611 and 1613 to 1617 and the inverter 1618 that are input/output consistent do not change. On the other hand, the output value of the buffer 1612 that is not input/output consistent changes from “0” to “1” (the signal further proceeds by one stage).

In this manner, each time a delay time t_{buff} corresponding to one buffer stage elapses, the output value of one of the buffers 1611 to 1617 and the inverter 1618 that is not input/output consistent changes from “0” to “1” in order. Then, after 8×t_{buff} elapses from when the oscillation switch 1630 was switched on, the output values of all of the buffers and inverter change to “1” (one signal cycle complete). When 8×t_{buff} further elapses (after 16×t_{buff} elapses), the output values of all of the buffers and inverter change to “0” (two signal cycles complete), the state returns to the original state.

Thereafter, output changes in a similar manner in a cycle of 16×t_{buff}. In this manner, the time resolution of the high resolution TDC 1501 equals to t_{buff}. In addition, the time resolution t_{buff} is adjusted to 2⁻⁷ ( 1/128)×the cycle of a synchronous clock by a later-described first oscillation adjusting circuit 1541.

In addition, oscillator output, that is, output of the inverter 1618 is input to the first oscillation count circuit 1521. The first oscillation count circuit 1521 measures a time period with the time resolution of 16×t_{buff}, by counting a rising edge of the oscillator output.

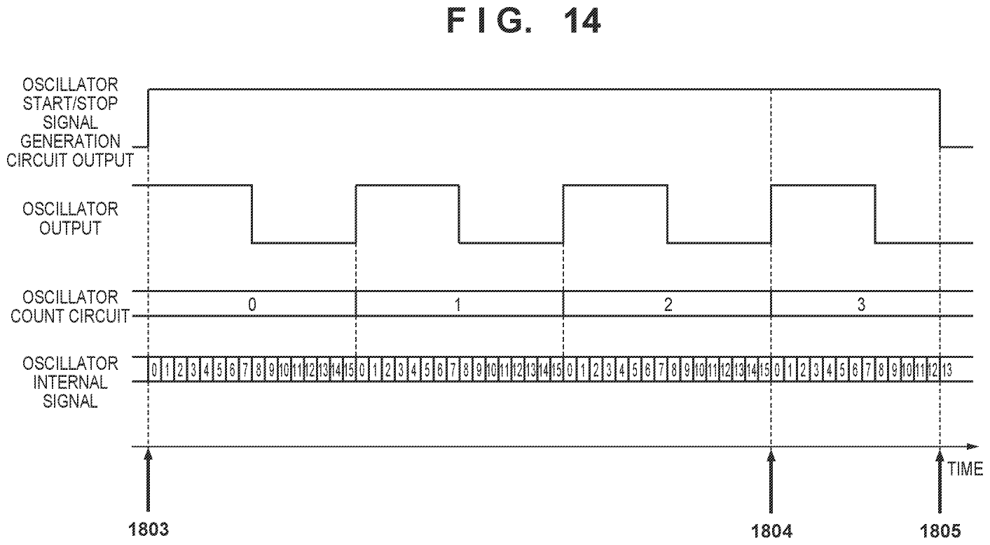

FIG. 13 is a timing chart to the end of measurement of a time period from when light is emitted until when reflected light is detected by the SPAD element 1401. The timing chart shows changes in the cathode potential Vc of the SPAD element 1401, a pixel output signal, a synchronous clock, a count value of the synchronous clock count circuit, output of the oscillator start/stop signal generation circuit, oscillator output, and a count value of the oscillation count circuit.

The cathode potential Vc of the SPAD element 1401 is an analog voltage, and an upper portion of the timing chart in the figure indicates a higher voltage. The synchronous clock, the output of the oscillator start/stop signal generation circuit, and the oscillator output are digital signals, and upper portions of the timing charts in the figure indicate that the signals are on, and lower portions indicate that they are off. The count values of the synchronous clock count circuit and the oscillator count circuit are digital values, and are expressed in decimal numbers.

FIG. 14 is a diagram showing, in an enlarged manner, the output of the oscillator start/stop signal generation circuit, the oscillator output, and the count value of the oscillator count circuit, from time 1803 until time 1805 in FIG. 13, and the oscillator internal signal. The oscillator internal signal takes a digital value, and is expressed in a decimal number.

An operation of measuring, with the high resolution TDC 1501, a time period from time 1801 when the light source unit 111 emits light until time 1803 when a photon is incident on the SPAD element 1401 of a pixel and the pixel output signal changes from 0 to 1 will be described with reference to FIGS. 13 and 14.

The light source control unit 113 drives the light source unit 111 such that the light-emitting elements 211 emit light at time 1801 that is synchronized with a rise of a synchronous clock supplied via the overall control unit 140. When an instruction to start measurement is given from the overall control unit 140 at time 1801 when the light-emitting element 211 emits light, the first synchronous clock count circuit 1531 starts counting a rising edge of a synchronous clock.

When reflected light of the light emitted at time 1801 is incident on a pixel at time 1803, the cathode potential Vc of the SPAD element 1401 drops, and the pixel output signal changes from “0” to “1”. When the pixel output signal changes to “1”, the output of the oscillation start/stop signal generation circuit 1640 changes from “0” to “1”, and the oscillation switch 1630 is switched on.

When the oscillation switch 1630 is switched on, an oscillation operation is started, and a signal loop is started inside the oscillator as shown in FIG. 12. Every time 16×t_{buff} elapses from when the oscillation switch 1630 was switched on and two signal cycles are complete in the oscillator, a rising edge emerges on the oscillator output, and the first oscillation count circuit 1521 measures the number of the rising edges. In addition, at time 1803, the first synchronous clock count circuit 1531 stops counting, and holds the count value.

At time 1803 when the first oscillator 1511 was switched on, and from time 1803, a first timing when the synchronous clock rises is time 1805. As the synchronous clock rises at time 1805, the output value of the oscillation start/stop signal generation circuit 1640 changes to “0”, and the oscillation switch 1630 is switched off. At the timing when the oscillation switch 1630 changes to “0”, oscillation of the first oscillator 1511 ends, and an oscillation circuit internal signal is held as is. In addition, since oscillation ends, the first oscillation count circuit 1521 also stops counting.

A count result D_{Gclk} of the synchronous clock count circuit is a value obtained by measuring a time period from time 1801 until time 1802 in units of 2⁷×t_{buff}. In addition, a count result D_{ROclk} of the oscillator count circuit is a value obtained by measuring a time period from time 1803 until time 1804 in units of 2⁴×t_{buff}. Furthermore, an oscillator internal signal D_{ROin} takes a value obtained by measuring a time period from time 1804 until time 1805 in units of t_{buff}. The high resolution TDC 1501 performs the following processing on these values, and outputs the resultants to the signal processing unit 123, thereby completing one measurement operation.

The count result D_{ROclk} of the oscillator count circuit and the oscillator internal signal D_{ROin} are added in accordance with Expression 2 below.

D_{RO}=2⁴×D_{ROclk}+D_{ROin} (2)

D_{RO} obtained using Expression 2 is a value obtained by measuring a time period from time 1803 until time 1805 in units of t_{buff}. In addition, a time period from time 1802 until time 1805 equals to one cycle of the synchronous clock, and thus is 2⁷×t_{buff}. For this reason, by subtracting D_{RO} from one cycle of the synchronous clock, the time period from time 1802 until time 1803 is obtained. When the time period from time 1802 until time 1803 is added to D_{Gclk}, namely a time period from time 1801 until time 1802, a value D_{ToF} indicating the time period from time 1801 until time 1803 measured in units of t_{buff} is obtained (Expression 3).

D_{Tof}=2⁷×D_{Gclk}+(2⁷−D_{RO})=2⁷×D_{Gclk}+(+(2⁷−24×D_{ROclk}−D_{ROin}) (3)

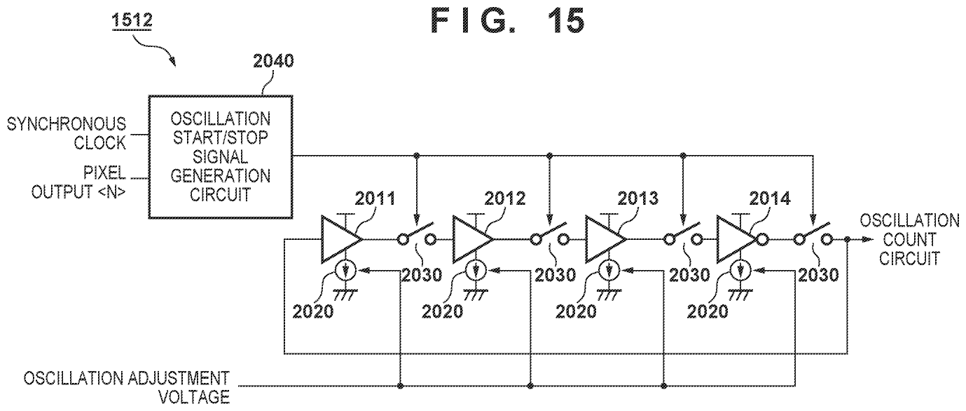

FIG. 15 is a diagram schematically showing an exemplary circuit configuration of the second oscillator 1512 of the low resolution TDC 1502. In the second oscillator 1512, buffers 2011 to 2013 and an inverter 2014 are alternately connected to oscillation switches 2030 in series in a ring shape. In addition, delay-adjusting current sources 2020 are respectively provided to the buffers 2011 to 2013 and the inverter 2014, and adjust the delay times of the corresponding buffers and inverter in accordance with an adjusting voltage.

Compared with the high resolution TDC 1501, the number of buffers and the number of oscillation switches are smaller, and are three instead of seven. On the other hand, a delay time t_{buff} of the buffers 2011 to 2013 and the inverter 2014 are adjusted to 2×t_{buff} of the high resolution TDC 1501 by a second oscillation adjusting circuit 1542.

Accordingly, the count cycle of the second oscillation count circuit 1522 equals to the count cycle of the first oscillation count circuit 1521. Therefore, the number of output bits of the second oscillation count circuit 1522 equals to the number of output bits of the first oscillation count circuit 1521. On the other hand, the number of bits of the oscillator internal signal of the second oscillator 1512 can be made smaller than that of the first oscillator 1511 by one bit.

As described above, it is envisioned that the low-sensitivity pixels L are mainly used for long distance range-finding. The influence that the ToF measurement resolution has on the accuracy of a range-finding result for a short distance is greater than that for a long distance. For this reason, the ToF measurement resolution with which the low resolution TDC 1502 measures ToFs of the low-sensitivity pixels L is lower than that of the high resolution TDC 1501, giving priority to reducing the circuit scale and the power consumption.

A delay time t_{buff} varies due to a factor such as a manufacturing error of a transistor that is caused by a manufacturing process, a change in a voltage that is applied to a TDC circuit, and a temperature. For this reason, the first oscillation adjusting circuit 1541 and the second oscillation adjusting circuit 1542 are provided for every eight TDCs.

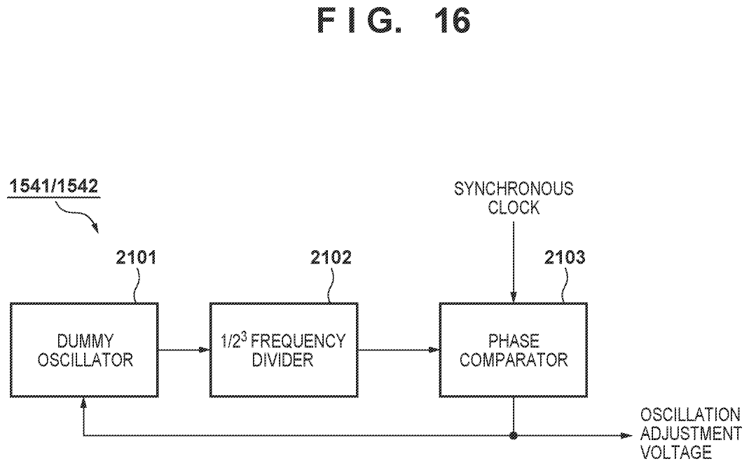

FIG. 16 is a block diagram showing an exemplary functional configuration of the first oscillation adjusting circuit 1541 and the second oscillation adjusting circuit 1542. The first oscillation adjusting circuit 1541 and the second oscillation adjusting circuit 1542 have the same configuration, and thus the first oscillation adjusting circuit 1541 will be described below. The first oscillation adjusting circuit 1541 includes a dummy oscillator 2101, ½³ (⅛) frequency divider 2102, and a phase comparator 2103.

The dummy oscillator 2101 is an oscillator having the same configuration as the oscillator of a TDC that is connected thereto. Therefore, the dummy oscillator 2101 of the first oscillation adjusting circuit 1541 has the same configuration as the first oscillator 1511. The dummy oscillator 2101 of the second oscillation adjusting circuit 1542 has the same configuration as the second oscillator 1512.

Output of the dummy oscillator 2101 is input to the ½³ frequency divider 2102. The ½³ frequency divider 2102 outputs a clock signal obtained by changing the frequency of an input clock signal to ½³. A synchronous clock and output of the ½³ frequency divider 2102 are input to the phase comparator 2103. The phase comparator 2103 compares the frequency of the synchronous clock and the frequency of the clock signal output by the ½³ frequency divider 2102 with each other.

Then, the phase comparator 2103 increases an output voltage if the frequency of the synchronous clock signal is higher, and decreases the output voltage if the frequency of the synchronous clock is lower. Output of the phase comparator 2103 is input as an adjusting voltage to the delay-adjusting current source 1620 of the first oscillator 1511, and delay is adjusted such that the oscillation frequency of the first oscillator 1511 is 2³ times as high as the synchronous clock. The same applies to the second oscillation adjusting circuit 1542.

In this manner, an oscillation frequency of the oscillator is determined using a synchronous clock frequency as a reference. For this reason, by generating a synchronous clock signal using an external IC that can output a fixed frequency irrespective of a change in the process/voltage/temperature, it is possible to suppress variation in the oscillation frequency of the oscillator due to a change in the process/voltage/temperature.

By inputting a clock signal of 160 MHz as a synchronous clock signal, for example, oscillation frequencies for both the high resolution TDC 1501 and the low resolution TDC 1502 are eight times the synchronous clock frequency, namely 1.28 GHz. A delay time t_{buff} for one buffer stage that is the time resolution of a TDC is 48.8 ps for the high resolution TDC 1501, and 97.7 ps for the low resolution TDC 1502.

### Range Finding Sequence

FIG. 17 is a flowchart related to an example of a range-finding operation according to the present embodiment.

In step S2201, the overall control unit 140 resets a histogram circuit and a measurement counter i of the signal processing unit 123. Also, the overall control unit 140 changes connection of the relay buffer (not illustrated) such that output of pixels 511 optically corresponding to light-emitting elements 211 that emit light in step S2202 is input to the TDC array unit 122.

In step S2202, the overall control unit 140 causes some of the light-emitting elements 211 that constitute the light source array 210 of the light source unit 111 to emit light. At the same time, the overall control unit 140 instructs the TDC array unit 122 to start measurement.

The high resolution TDCs 1501 and the low resolution TDCs 1502 of the TDC array unit 122 output measurement results to the signal processing unit 123, when a change in output of the corresponding pixels 511 from “0” to “1” is detected. When a time corresponding to a predetermined maximum range-finding range has elapsed from when light was emitted, step S2204 is executed.

In step S2204, the signal processing unit 123 adds the measurement results obtained in step S2203 to the histograms of the respective pixels. The signal processing unit 123 does not add a measurement result to a histogram with respect to a pixel for which no measurement result has been obtained.

In step S2205, the signal processing unit 123 adds 1 to the value of a number-of-measurements counter i.

In step S2206, the signal processing unit 123 determines whether or not the value of the number-of-measurements counter i is larger than the present number of times Nₜₒₜₐₗ. The signal processing unit 123 executes step S2207 if it is determined that the value of the number-of-measurements counter i is larger than the preset number of times Nₜₒₜₐₗ, and executes 2202 if it is not determined that the value of the number-of-measurements counter i is larger than the preset number of times Nₜₒₜₐₗ.

In step S2207, the signal processing unit 123 removes counting results considered to be noise components, based on the histograms of the individual pixels, and executes step S2208.

In step S2208, the signal processing unit 123 averages measurement results that remained without being removed in step S2207, regarding the histograms of individual pixels, outputs the average value as a measured ToF, and ends a range-finding sequence once.

### Noise Light Suppressing Effects Achieved by Using Pixels Having Different Sensitivities

Here, noise component removal processing in step S2207 and averaging in step S2208 will be described, and, after that, noise light reducing effects achieved by using pixels H and the pixels L having different sensitivities will be described.

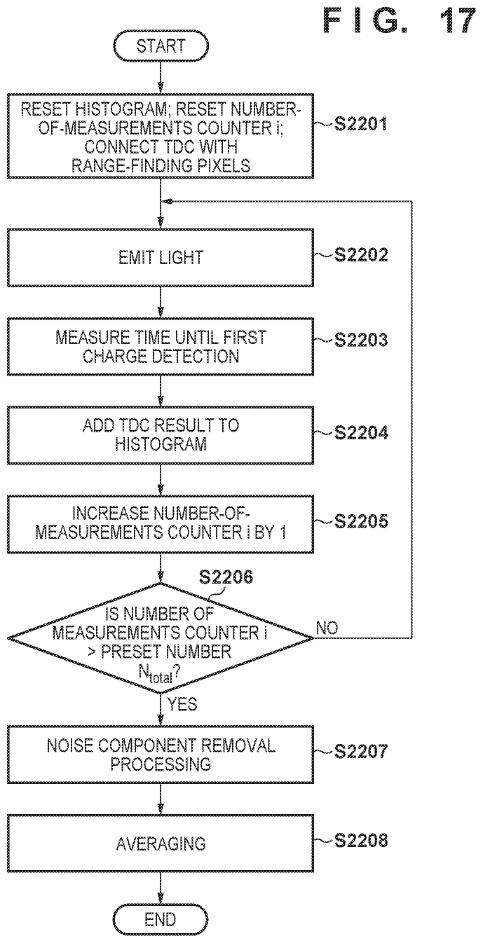

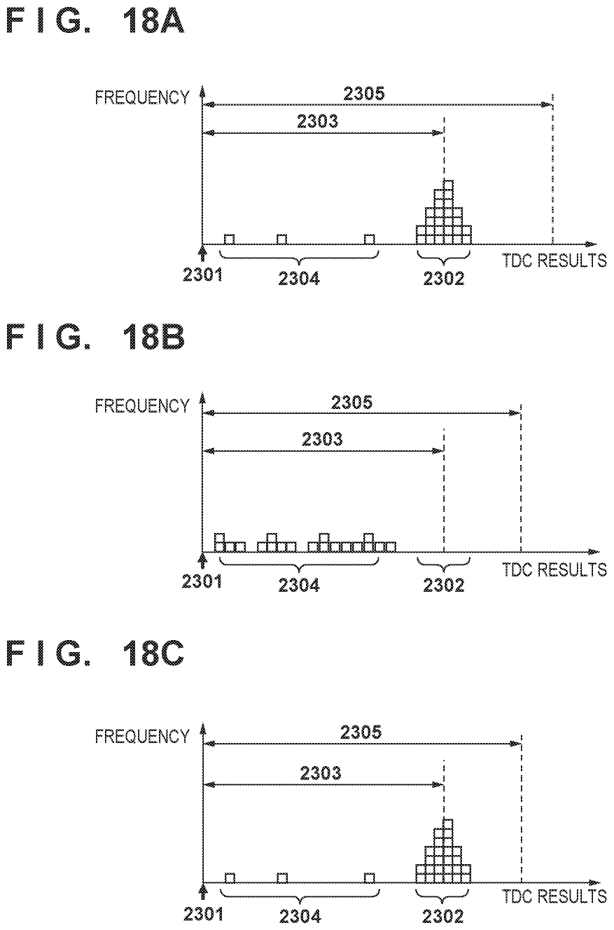

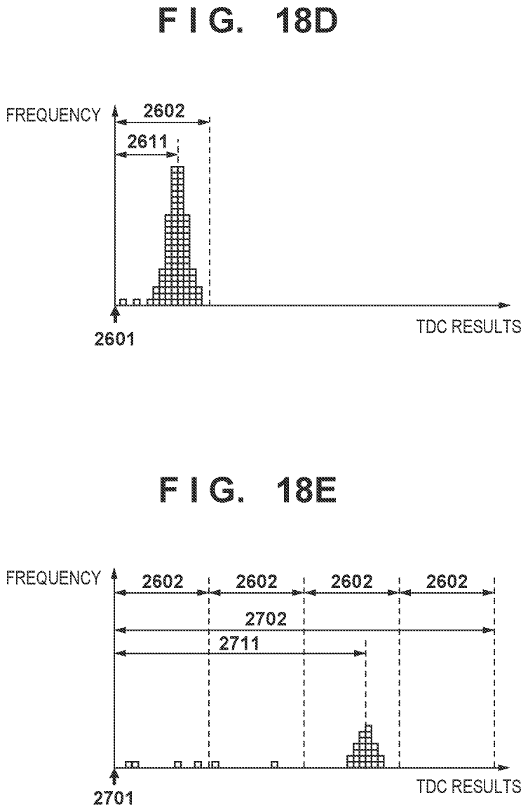

FIG. 18A is a diagram showing an example of a histogram of results of TDC measurement performed the number of times Nₜₒₜₐₗ in a high-sensitivity pixel H. The horizontal axis indicates TDC measurement result (time period), and the vertical axis indicates frequency/the number of times of measurement. Note that the bin width of the TDC measurement result is set for convenience.

Since measurement results included in a section 2302 include a frequency peak/a peak in the number of times of measurement, it is conceivable that the measurement results are correct measurement results of time periods from when light was emitted until light was received. On the other hand, since measurement results included in a section 2304 are distributed irregularly and sparsely, it is conceivable that noise light such as ambient light that randomly occurs or a noise component caused by a dark count is included. Therefore, the measurement results included in the section 2304 are removed, and the average 2303 of only the measurement results included in the section 2302 is used as a range-finding result.

Similarly to FIG. 18A, FIG. 18B is also a diagram showing an example of a histogram of results of TDC measurement performed the number of times Nₜₒₜₐₗ in a high-sensitivity pixel H. The subject in FIG. 18B is the same as that in FIG. 18A, but FIG. 18B shows an example of a histogram of TDC measurement results obtained in a situation where there is more ambient light than that for the measurements shown in FIG. 18A. TDC measurement ended when performed the number of times Nₜₒₜₐₗ due to noise light included in the section 2304, and no TDC measurement result for reflected light from the subject has been obtained.

FIG. 18C is a diagram showing an example of a histogram of results of TDC measurement performed the number of times Nₜₒₜₐₗ in a low-sensitivity pixel L in the same environment as that in FIG. 18B. Since the low-sensitivity pixel L has a lower sensitivity than the high-sensitivity pixel H, the number of times TDC measurement is performed on noise light is smaller. As a result, the number of measurement results included in the section 2302 is larger, and similarly to FIG. 18A, the average value of measurement results included in the section 2302 can be computed as a range-finding result. In this manner, the low-sensitivity pixel L is more resistant in a situation where there is great ambient light noise than the high-sensitivity pixel H.

Note that, here, a situation that can occur in an environment where there is great noise light has been described. However, a similar problem can also occur when an object that is a range-finding target is far away. This is because, when there is an object that is far away, a time period from light emission until when reflected light returns (that is to say, a time period during which noise light is detected) is long.

In the present embodiment, by using the high-sensitivity pixels H and the low-sensitivity pixels L, stable range finding can be performed with the influence of noise light being suppressed, even when the amount of noise light is large or range finding is performed on a distant object. Furthermore, the configuration of light receiving elements (SPADs) (light receiving area and the thickness of light-receiving part), and a voltage that is applied to the light receiving elements are common to the high-sensitivity pixels H and the low-sensitivity pixels L. For this reason, variation between a range-finding result obtained in a high-sensitivity pixel H and a range-finding result obtained in a low-sensitivity pixel L is small, and an accurate range-finding result is obtained.

### HDR Driving Method

Next, HDR driving of a high-sensitivity pixel H and a low-sensitivity pixel L will be described with reference to FIGS. 18D and 18E. FIG. 18D shows an example of a histogram of measurement results for a high-sensitivity pixel H, and FIG. 18E shows an example of a histogram of measurement results for a low-sensitivity pixel L adjacent to the high-sensitivity pixel H in FIG. 18D.

The light-emitting period of the light-emitting element 211 corresponding to the high-sensitivity pixel H is denoted by 2602, and the light-emitting period of the light-emitting element 211 corresponding to the low-sensitivity pixel L is denoted by 2702. The light-emitting period 2702 is four times the light-emitting period 2602. For this reason, during the same time period, the number of times range-finding can be performed for the high-sensitivity pixel H is four times larger than the number of times range-finding can be performed for the low-sensitivity pixel L. It is highly likely that the number of range-finding results for the high-sensitivity pixel H that are averaged will be larger than for the low-sensitivity pixel L, and measurement for the pixel H having a favorable sensitivity is performed by the high resolution TDC 1501, and thus the range-finding accuracy in a space corresponding to the high-sensitivity pixel H is higher than the range-finding accuracy in a space corresponding to the low-sensitivity pixel L.

When an object that is a range-finding target is at a long distance, a ToF is long, and thus it is highly likely that noise light will be measured. The light-emitting elements 211 corresponding to the low-sensitivity pixels L that have a high noise light suppressing effect do not perform next light emission until reflected light is detected. On the other hand, the light-emitting elements 211 corresponding to the high-sensitivity pixels H that have a low noise light suppressing effect perform next light emission before reflected light is detected. Accordingly, it is possible to shorten a time period from when the TDC starts measurement until when reflected light is detected, and to suppress the probability of noise light being measured during the time period from when light is emitted until when reflected light arrives, and, even in an environment in which noise light is significant, accurate time-period measurement can be performed for the high-sensitivity pixels H.

The signal processing unit 123 applies offset correction that is based on measurement results obtained for the adjacent low-sensitivity pixel L, to measurement results obtained for the high-sensitivity pixel H. Offset correction is to add a value obtained by multiplying the light-emitting period (measurement period) 2602 of the high-sensitivity pixel H by a constant, to a measurement result 2611 for the high-sensitivity pixel H, based on a measurement result 2711 for the adjacent low-sensitivity pixel L.

Since the measurement result 2711 is obtained for the low-sensitivity pixel L adjacent to the high-sensitivity pixel H, it is highly likely that a time period until when reflected light of emitted light arrives in the high-sensitivity pixel H is close to the measurement result 2711. In the examples in FIGS. 18D and 18E, the measurement result 2711 for the low-sensitivity pixel L is higher than twice the light-emitting period 2602 for the high-sensitivity pixel H and is smaller than three times. For this reason, in offset correction, the signal processing unit 123 adds a time period that is twice the light-emitting period 2602, to the measurement result 2611 for the high-sensitivity pixel H.

Note that an offset correction amount may be determined based on measurement results obtained for two or more low-sensitivity pixels L adjacent to a high-sensitivity pixel H that is a correction target. The offset correction amount may be determined based on measurement results obtained for four or two low-sensitivity pixels L adjacent to the high-sensitivity pixel H in the horizontal direction and/or the vertical direction, for example.

In addition, a configuration may also be adopted in which an image capturing unit that captures an image in the light-projection range of the light-projection unit 110 is provided, and low-sensitivity pixels L to be used for determining an offset correction amount is specified using a captured image. The signal processing unit 123 specifies, based on a captured image, one or more adjacent low-sensitivity pixels L in which range finding is considered to be being performed for the same subject as the high-sensitivity pixel H that is a correction target, for example. The signal processing unit 123 may then determine an offset correction amount (or a coefficient by which the light-emitting period of the high-sensitivity pixel H is to be multiplied) using measurement results obtained for the specified low-sensitivity pixels L.

According to the present embodiment, by using light receiving elements having different sensitivities, it is possible to realize a light-receiving device having a wide dynamic range. In addition, the sensitivities of the light receiving elements differ due to optical components added to the light receiving elements. For this reason, it is possible to use light receiving elements having the same configuration, and it is advantageous from viewpoint of ease of manufacturing and suppression of variation in characteristics. In addition, lower resolution of time measurement is set for the low-sensitivity pixels than high-sensitivity pixels, and thereby it is possible to efficiently reduce the circuit scale and power consumption while suppressing a decrease in the range-finding accuracy.

According to the present invention, it is possible to provide a new technique for realizing a light-receiving device that has a wide dynamic range.

### Other Embodiment

The above-described range finding apparatus can be mounted in any electronic device that includes processing means for executing predetermined processing using distance information. Examples of such an electronic device includes image capture apparatuses, computer devices (personal computers, tablet computers, media players, PDAs, etc.), mobile phones, smartphones, game machines, robots, drones, and vehicles. These are exemplary, and the range finding apparatus according to the present invention can also be mounted in other electronic devices.

Embodiment(s) of the present invention can also be realized by a computer of a system or apparatus that reads out and executes computer executable instructions (e.g., one or more programs) recorded on a storage medium (which may also be referred to more fully as a ‘non-transitory computer-readable storage medium’) to perform the functions of one or more of the above-described embodiment(s) and/or that includes one or more circuits (e.g., application specific integrated circuit (ASIC)) for performing the functions of one or more of the above-described embodiment(s), and by a method performed by the computer of the system or apparatus by, for example, reading out and executing the computer executable instructions from the storage medium to perform the functions of one or more of the above-described embodiment(s) and/or controlling the one or more circuits to perform the functions of one or more of the above-described embodiment(s). The computer may comprise one or more processors (e.g., central processing unit (CPU), micro processing unit (MPU)) and may include a network of separate computers or separate processors to read out and execute the computer executable instructions. The computer executable instructions may be provided to the computer, for example, from a network or the storage medium. The storage medium may include, for example, one or more of a hard disk, a random-access memory (RAM), a read only memory (ROM), a storage of distributed computing systems, an optical disk (such as a compact disc (CD), digital versatile disc (DVD), or Blu-ray Disc (BD)™), a flash memory device, a memory card, and the like.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

1. A light-receiving device comprising
a pixel array in which a first pixel provided with a first optical band pass filter and having a first sensitivity and a second pixel provided with a second optical band pass filter and having a second sensitivity that is lower than the first sensitivity are two-dimensionally arranged,
wherein a full width at half maximum of the second optical band pass filter is narrower than a full width at half maximum of the first optical band pass filter.

2. The light-receiving device according to claim 1, wherein
a dimming member or a mask is added to a light receiving element of the second pixel, as an optical element.

3. The light-receiving device according to claim 1, wherein
light receiving elements of the first pixel and the second pixel are avalanche photodiodes.

4. The light-receiving device according to claim 1, wherein
central wavelengths of passbands of the first optical band pass filter and the second optical band pass filter are the same.

5. The light-receiving device according to claim 1, wherein
the first pixel and the second pixel are alternately arranged.

6. A range finding apparatus comprising:
a light-receiving device; and
one or more processors that execute a program stored in a memory and thereby function as:
a measuring unit configured to measure time periods from a predetermined time until times when light is incident on the first pixel and the second pixel, respectively; and
a computing unit configured to compute distance information for the first pixel and distance information for the second pixel based on the measured time periods,
wherein the light-receiving device comprising
a pixel array in which a first pixel provided with a first optical band pass filter and having a first sensitivity and a second pixel provided with a second optical band pass filter and having a second sensitivity that is lower than the first sensitivity are two-dimensionally arranged,
wherein a full width at half maximum of the second optical band pass filter is narrower than a full width at half maximum of the first optical band pass filter.

7. The range finding apparatus according to claim 6, wherein
the predetermined time is a time when the light-emitting device emits light.

8. The range finding apparatus according to claim 7, wherein
the light-emitting device includes a plurality of light-emitting elements that are two-dimensionally arranged, and
each of the plurality of light-emitting elements is configured to correspond to a specific pixel of the light-receiving device.

9. The range finding apparatus according to claim 8, wherein
a light-emitting cycle of a light-emitting element corresponding to the first pixel among the plurality of light-emitting elements is shorter than a light-emitting cycle of a light-emitting element corresponding to the second pixel.

10. The range finding apparatus according to claim 9, wherein
the time period measured for the first pixel is corrected based on the time period measured for the second pixel that is adjacent to the first pixel.

11. An electronic device comprising:
a range finding apparatus; and
one or more processors that execute a program stored in a memory and thereby function as a processing unit configured to execute predetermined processing using distance information obtained by the range finding apparatus,
wherein the range finding apparatus comprises:
a light-receiving device; and
one or more processors that execute a program stored in a memory and thereby function as:
a measuring unit configured to measure time periods from a predetermined time until times when light is incident on the first pixel and the second pixel, respectively; and
a computing unit configured to compute distance information for the first pixel and distance information for the second pixel based on the measured time periods,
wherein the light-receiving device comprising
a pixel array in which a first pixel provided with a first optical band pass filter and having a first sensitivity and a second pixel provided with a second optical band pass filter and having a second sensitivity that is lower than the first sensitivity are two-dimensionally arranged,
wherein a full width at half maximum of the second optical band pass filter is narrower than a full width at half maximum of the first optical band pass filter.
